(19) United States
(12) Patent Application Publication
(10) Pub. No.: US 2026/0255515 A1
(43) Pub. Date: Aug. 27, 2026

(54) WINDOW, ELECTRIC DEVICE COMPRISING THE SAME AND METHOD FOR MANUFACTURING THE SAME

(71) Applicant: Samsung Display Co., Ltd., Yongin-si (KR)

(72) Inventor: Jonghwan CHO, Yongin-si (KR)

(73) Assignee: Samsung Display Co., Ltd., Yongin-si (KR)

(21) Appl. No.: 19/359,165

(22) Filed: Oct. 15, 2025

(30) Foreign Application Priority Data
Feb. 26, 2025 (KR) 10-2025-0025089

(51) Int. Cl. H05K 5/03; C03C 17/30; C09D 183/06; C09D 183/08

(52) U.S. Cl. CPC H05K 5/03; C09D 183/06; C09D 183/08; C03C 17/30; C03C 2218/151

(57) ABSTRACT

The present disclosure provides a window, an electronic device including the window, and a method of manufacturing the window. Particularly, the present disclosure provides a window having low-refraction characteristics and high-hardness characteristics by sequentially depositing copolymers respectively including a fluoro-based silsesquioxane polymer chain, an acrylic-based silsesquioxane polymer chain and a fluoro-based silsesquioxane polymer chain, and an acrylic-based silsesquioxane polymer chain, an electronic device including the window and a method of manufacturing the window.

### CROSS-REFERENCE TO RELATED APPLICATION

The present application claims priority to and the benefit of Korean Patent Application No. 10-2025-0025089, filed on Feb. 26, 2025, in the Korean Intellectual Property Office, the entire content of which is incorporated herein by reference.

### BACKGROUND

### 1. Field

The present disclosure relates to a window, an electronic device including the same, and a method of manufacturing the same.

Foldability and flexibility of an electronic device, such as an organic light-emitting diode (OLED), a liquid crystal display (LCD), and a plasma display panel, are being emphasized. A foldable or flexible electronic device may have a shape variously modified by folding, bending or sliding a display screen. Therefore, under the circumstances, there is a need to develop a window having excellent glare and reflection protection characteristics for indoor and outdoor use without deterioration of mechanical properties.

Currently, development for improvement of foldability and low-reflection characteristics of a window constantly continues.

### SUMMARY

An object of the present disclosure is to provide a window having low-reflection characteristics and configured to prevent a crack by having excellent foldability properties, an electronic device including the same, and a method of manufacturing the same.

Objects of the present disclosure are not limited to the described object, and other undescribed technical objects shall be clearly understood by a person ordinarily skilled in the art from the following descriptions.

A window according to one embodiment includes a base film and a refraction layer on the base film, wherein the refraction layer includes a first silsesquioxane copolymer including a fluoro-based silsesquioxane polymer chain, a second silsesquioxane copolymer including an acrylic-based silsesquioxane polymer chain, and a third silsesquioxane copolymer including the first silsesquioxane copolymer and the second silsesquioxane copolymer, and wherein the refraction layer has the second silsesquioxane copolymer, the third silsesquioxane copolymer and the first silsesquioxane copolymer sequentially (e.g., in the stated order) laminated on the base film.

In one embodiment, the first silsesquioxane copolymer may be a compound represented by Formula 1 below, and the second silsesquioxane copolymer may be a compound represented by Formula 2 below.

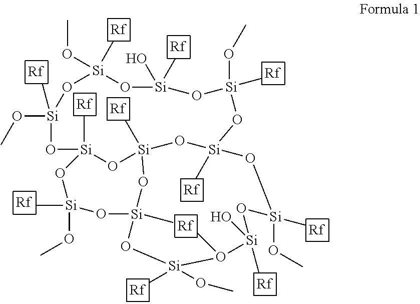

In Formula 1, Rf may be (CF₂)ₙ-M, M may be selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group (e.g., a phenyl group) with CF₃, a cyano group, a nitro group, a trifluoro methyl group, an amidino group, a hydrazine group, a hydrazono group, an alkoxy group, or any combination thereof, and n may be greater than or equal to 1 and less than or equal to 6.

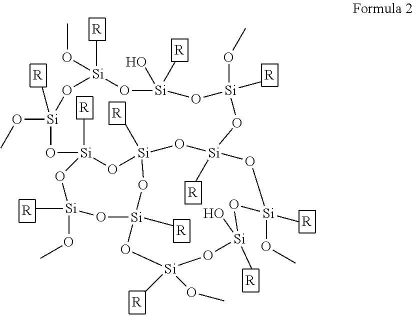

In Formula 2, R may be (—O—CO—Z)ₘ, Z may be selected from hydrogen, deuterium, a halogen, a hydroxyl group, a cyano group, a nitro group, a trifluoro methyl group, an amidino group, a hydrazine group, a hydrozono group, an alkoxy group, or any combination thereof; or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and m may be greater than or equal to 1 and less than or equal to 4.

In one embodiment of the present disclosure, in the third silsesquioxane copolymer, a weight ratio of the first silsesquioxane copolymer to the second silsesquioxane copolymer may be 1.1 to 1.1.5.

A refractive index of the first silsesquioxane and a refractive index of the third silsesquioxane copolymer may be smaller than a refractive index of the second silsesquioxane copolymer, and the refractive index of the first silsesquioxane copolymer may be smaller than the refractive index of the third silsesquioxane copolymer.

In one embodiment of the present disclosure, the refractive index of the first silsesquioxane copolymer may be greater than or equal to 1 and less than or equal to 1.7, the refractive index of the third silsesquioxane copolymer may greater than or equal to 1.2 and less than or equal to 1.8, and the refractive index of the second silsesquioxane copolymer may be greater than or equal to 1.3 and less than or equal to 2.

In one embodiment of the present disclosure, a deposition thickness of the third silsesquioxane copolymer may be thinner than a respective deposition thickness of the first silsesquioxane copolymer and the second silsesquioxane copolymer, and a deposition thickness of the first silsesquioxane copolymer may be thinner than a deposition thickness of the second silsesquioxane copolymer.

In one embodiment of the present disclosure, the thickness of the first silsesquioxane may be greater than or equal to 50 nm and less than or equal to 100 nm, the thickness of the second silsesquioxane copolymer may be greater than or equal to 10 nm and less than or equal to 50 nm, and the thickness of the third silsesquioxane copolymer may be greater than or equal to 100 nm and less than or equal to 200 nm.

In one embodiment of the present disclosure, a luminous reflectance of the window may be less than or equal to 0.8%.

In one embodiment of the present disclosure, a crack may not occur in the window under a folding condition of a radius curvature greater than or equal to 1.4 R and less than or equal to 5R.

In one embodiment of the present disclosure, the refraction layer may be a single layer refraction layer having low-reflection characteristics and high-hardness hard-coated characteristics.

In one embodiment of the present disclosure, the refraction layer may have anti-fog (AG) characteristics.

In one embodiment of the present disclosure, the window may further include a coated layer having high-hardness and high-flexibility properties on the base film.

In one embodiment of the present disclosure, an elasticity of the coated layer may be greater than or equal to 6 GPa and less than or equal to 8 GPa at a depth greater than or equal to 200 nm and less than or equal to 400 nm or greater than or equal to 500 and less than or equal to 800 nm.

In one embodiment of the present disclosure, a hardness of the coated layer may be greater than or equal to 0.6 GPa and less than or equal to 0.7 GPa at a depth greater than or equal to 200 nm and less than or equal to 400 nm or greater than or equal to 500 nm and less than or equal to 800 nm.

A method of manufacturing a window according to one embodiment of the present disclosure may include (I) first depositing for deposition of a second silsesquioxane copolymer represented by Formula 2 on a base film, (II) second depositing for deposition of a third silsesquioxane copolymer generated through a polymerization reaction by evaporating a first silsesquioxane copolymer represented by Formula 1 and the second silsesquioxane copolymer on the deposited second silsesquioxane copolymer, and (III) third depositing for deposition of the first silsesquioxane copolymer on the deposited third silsesquioxane copolymer for sequential deposition.

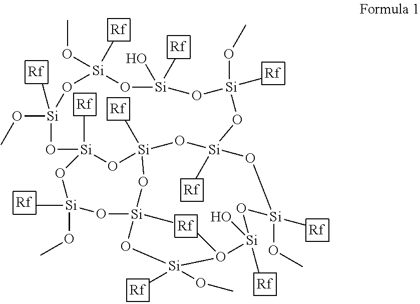

In Formula 1, Rf may be (CF₂)ₙ-M, M may be selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group (e.g., a phenyl group) with CF₃, a cyano group, a nitro group, a trifluoro methyl group, an amidino group, a hydrazine group, a hydrazono group, an alkoxy group, or any combination thereof, and n may be greater than or equal to 1 and less than or equal to 6.

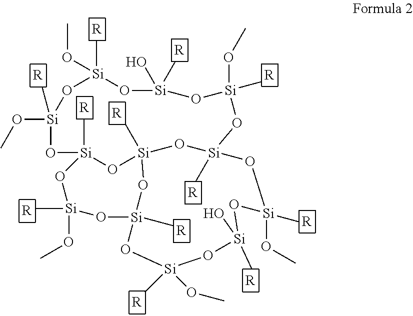

In Formula 2, R may be (—O—CO—Z)ₘ, Z may be selected from hydrogen, deuterium, a halogen, a hydroxyl group, a cyano group, a nitro group, a trifluoro methyl group, an amidino group, a hydrazine group, a hydrozono group, an alkoxy group, or any combination thereof, or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and m may be greater than or equal to 1 and less than or equal to 4.

In one embodiment of the present disclosure, in the polymerization reaction, the first silsesquioxane copolymer and the second silsesquioxane copolymer may be polymerized to a polymer chain or a polymer side chain.

In one embodiment of the present disclosure, the first depositing (I) may further include depositing a coated layer on the base film prior to the first depositing.

In one embodiment, the first depositing (I) through the third depositing (III) may be performed through a vacuum deposition by irradiating an electron beam of greater than or equal to 200 KeV and less than or equal to 400 KeV in a vacuum environment.

In one embodiment of the present disclosure, the first silsesquioxane copolymer may be deposited to a thickness of greater than or equal to 50 nm and less than or equal to 100 nm, the second silsesquioxane copolymer may be deposited to a thickness of greater than or equal to 10 nm and less than or equal to 60 nm, and the third silsesquioxane copolymer may be deposited to a thickness of greater than or equal to 100 nm and less than or equal to 200 nm.

An electronic device according to one embodiment of the present disclosure may be an electronic device including a display panel including a display device and a window on an upper portion of the display panel, the window including a base film and a refraction layer on the base film, wherein the refraction layer includes a first silsesquioxane copolymer including a fluoro-based silsesquioxane polymer chain, a second silsesquioxane copolymer including an acrylic-based silsesquioxane polymer chain, and a third silsesquioxane copolymer including the first silsesquioxane copolymer and the second silsesquioxane copolymer, and wherein the refraction layer has the second silsesquioxane copolymer, the third silsesquioxane copolymer and the first silsesquioxane copolymer sequentially laminated (e.g., in the stated order) on the base film.

In one embodiment of the present disclosure, the electronic device may be a flat panel display, a curved display, a television, a billboard, a computer monitor, a medical monitor, a head mounted display (HMD), an indoor or outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual or augmented reality display, a video wall including multiple displays tiled together, a vehicle electronic device, an outdoor electronic device, a theater screen, a stadium screen, a scoreboard, a signboard, a game console, a refrigerator, a washing machine, a dryer, an air conditioner, or a robot vacuum cleaner

According to one embodiment of the present disclosure, a window according to the present disclosure may include a refraction layer including a fluoro-based silsesquioxane polymer, an acrylic-based silsesquioxane polymer and a combination thereof to have low-reflection properties and excellent foldability.

According to one embodiment of the present disclosure, an electronic device according to the present disclosure may include a window having excellent low-reflection characteristics and foldability to improve visibility and foldability.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a cross-sectional view schematically illustrating a window according to one embodiment;

FIG. 2 is a cross-section of a schematic diagram of a window having a first silsesquioxane copolymer through a third silsesquioxane copolymer vacuum deposited in a stepwise manner;

FIG. 3 illustrates a vector diagram simulation result of a window manufactured according to one embodiment of the present disclosure;

FIG. 4 illustrates a Z-fold structure of a conventional foldable electronic device;

FIG. 5 illustrates a G-fold structure of a conventional foldable electronic device;

FIG. 6 is a schematic cross-section of a window with a coated layer added according to one embodiment of the present disclosure;

FIG. 7 illustrates a schematic diagram of a first silsesquioxane polymer and a second silsesquioxane polymer of a window manufactured according to one embodiment of the present disclosure polymerized to a polymer chain (here, a cube refers to a mixture of (a) and (b));

FIG. 8 illustrates a schematic diagram of a first silsesquioxane polymer and a second silsesquioxane polymer of a window manufactured according to one embodiment of the present disclosure polymerized to a polymer side chain;

FIG. 9 is a plan view illustrating a display device according to one embodiment of the present disclosure;

FIG. 10 is a cross-section taken along the I-I′ line in FIG. 9;

FIG. 11 is a block diagram of an electronic device according to one embodiment of the present disclosure; and

FIG. 12 through FIG. 14 are schematic diagrams of an electronic device according to various embodiments of the present disclosure.

### DETAILED DESCRIPTION

Objects, specific advantages and new characteristics of the present disclosure will be much clarified with references to detailed descriptions and embodiments below in relation to the figures.

A term or word used in the specification or claims should not be interpreted in its usual or dictionary meaning, but should be construed to have the same meaning and concept that corresponds to the technical idea of the present disclosure based on a principle that the inventor can appropriately define the concept of the term to explain the inventor's invention in the best way.

When an element is described to be “on,” “placed on,” “arranged on,” “connected to,” or “coupled to” another element, it shall be construed as being on, placed on, arranged on, connected to, or coupled to the other element directly but also as possibly having another element arranged between the element and the other element. In contrast, when an element is described to be “directly on,” “directly placed on,” “directly arranged on,” “directly connected to,” or “directly coupled to” another element, it shall be construed that there is no other element arranged between the element and the another element.

A term used in the specification is used merely for explanation of specific embodiments, and it should not be construed to limit the present disclosure. Unless clearly used otherwise, any expressions in a singular form may include a meaning of a plural form.

As used herein, an expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

As used herein, when a part “comprises” an element, unless particularly described otherwise, another element is not excluded, but the other element may be further comprised. In addition, in the entire specification, the term “on” refers to being positioned above or below a subject portion, and it does not necessarily refer to being positioned on an upper side with respect to a gravitational direction.

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure. If a detailed description of a related known art may obscure the gist of the present disclosure in explaining the present disclosure, the detailed description will be omitted.

Hereinafter, embodiments of the present disclosure will be explained with reference to the figures. In the descriptions with reference to the figures, a same or corresponding component will be applied with a same figure reference, and a redundant description thereof will be omitted.

FIG. 1 is a cross-sectional view schematically illustrating a window according to one embodiment. Referring to FIG. 1, a window 1 including a base film 10 and a refraction layer 20 on the base film is provided. Particularly, the refraction layer 20 includes a first silsesquioxane copolymer 26 including a fluoro-based silsesquioxane polymer chain, a second silsesquioxane copolymer 22 including an acrylic-based silsesquioxane polymer chain, and a third silsesquioxane copolymer 24 including the first silsesquioxane copolymer 26 and the second silsesquioxane copolymer 22, and the refraction layer has the second silsesquioxane copolymer 22, the third silsesquioxane copolymer 24 and the first silsesquioxane copolymer 26 laminated on the base film 10.

Various known materials may be used for the base film, but the present disclosure is not limited thereto. The material of the base film will not be limited as long as it is a material to implement a window of the present disclosure

A unit of the first silsesquioxane copolymer 26 including a fluoro-based silsequioxane polymer chain and the second silsesquioxane copolymer 26 including an acrylic-based silsesquioxane polymer chain may be represented by a representative chemical formula (R′SiO_{1.5})ₓ. R′ may be selected from Rf, R or a hydroxy group, but the present disclosure is not limited thereto.

In one embodiment, Rf may be (CF₂)ₙ-M, M may be selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group (e.g., a phenyl group) with CF₃, a cyano group, a nitro group, a trifluoro methyl group, an amidino group, a hydrazine group, a hydrazono group, an alkoxy group, or any combination thereof, and n may be greater than or equal to 1 and less than or equal to 6.

In one embodiment, R may be (—O—CO—Z)ₘ, Z may be selected from hydrogen, deuterium, a halogen, a hydroxyl group, a cyano group, a nitro group, a trifluoro methyl group, an amidino group, a hydrazine group, a hydrozono group, an alkoxy group, or any combination thereof, or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and m may be greater than or equal to 1 and less than or equal to 4.

In one embodiment, the first silsesquioxane copolymer 26 may be a compound represented by Formula 1, and the second silsesquioxane copolymer 22 may be a compound represented by Formula 2, but the present disclosure is not limited thereto.

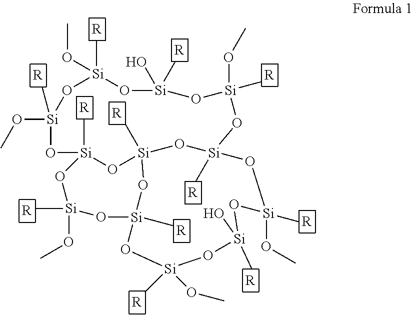

In Formula 1, Rf may be (CF₂)ₙ-M, M may be selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group (e.g., a phenyl group) with CF₃, a cyano group, a nitro group, a trifluoro methyl group, an amidino group, a hydrazine group, a hydrazono group, an alkoxy group, or any combination thereof, and n may be greater than or equal to 1 and less than or equal to 6.

In one embodiment, an alkyl group may have a linear chain or a branched chain. The number of carbons in the alkyl group may be 1 to 30, 1 to 20, or 1 to 10. Non-limiting examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylhexyl, 4-methylhexyl, and 5-methylhexyl.

In one embodiment, the alkenyl group may be an alkenyl group having 2 to 20 carbons, and the aryl group may be an aryl group having 6 to 30 ring-forming carbons (e.g., a phenyl group), but the present disclosure is not limited thereto.

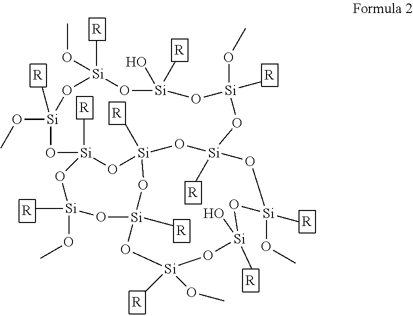

In Formula 2, R may be (—O—CO—Z)ₘ, Z may be selected from hydrogen, deuterium, a halogen, a hydroxyl group, a cyano group, a nitro group, a trifluoro methyl group, an amidino group, a hydrazine group, a hydrozono group, an alkoxy group, or any combination thereof; or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and m may be greater than or equal to 1 and less than or equal to 4.

In one embodiment, 11F-silsesquioxanetriol may be suitable as the first silsesquioxane copolymer 26, and 9H-silsesquioxanetriol or 18H-silsesquioxanetriol may be suitable as the second silsesquioxane copolymer 22, but the present disclosure is not limited thereto.

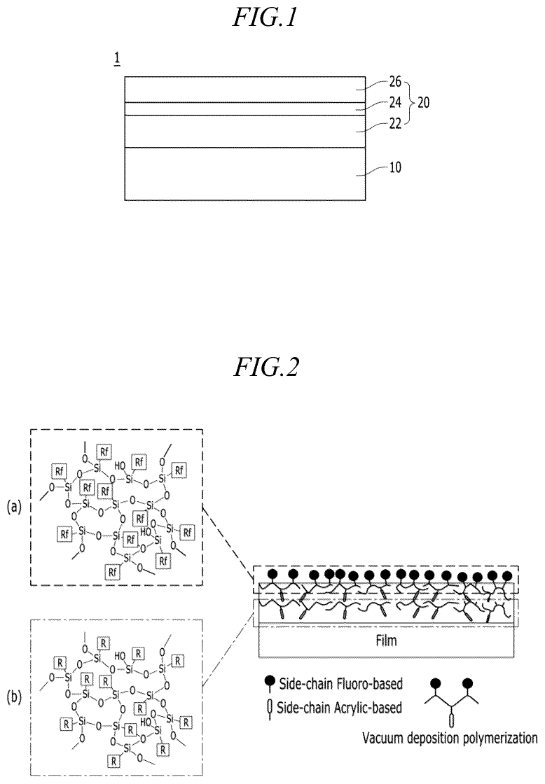

FIG. 2 is a cross-section of a schematic diagram of a window having a first silsesquioxane copolymer through a third silsesquioxane copolymer vacuum deposited in a stepwise manner. Referring to FIGS. 1 and 2, the second silsesquioxane copolymer 22 may be formed on the base film, i.e., in a lower portion of the refraction layer 20, the third silsesquioxane copolymer 24 formed by copolymerization of the first silsesquioxane copolymer 26 and the second silsesquioxane copolymer 22 may be formed on the second silsesquioxane copolymer 22, i.e., in a middle portion of the refraction layer 20, and the first silsesquioxane copolymer 26 may be formed on the third silsesquioxane copolymer 24, i.e., in an upper portion of the refraction layer 20.

In one embodiment of the present disclosure, the first silsesquioxane copolymer 26 provided on an outermost area of the window 1 in the refraction layer 20 of the present disclosure may include fluorine to have excellent slipperiness. Accordingly, in case that a fingerprint is formed or a contaminant is attached to a surface, it is easy to wipe it out, and touch sensitivity may be also improved upon application to a window.

In one embodiment, the third silsesquioxane copolymer 24 provided in the middle region of the refraction layer 20 of the present disclosure may have excellent chain polymerization reactivity and readily lead to a vacuum deposition polymerization reaction. The third silsesquioxane copolymer 24 may be generated through a polymerization reaction of the first silsesquioxane copolymer 26 and the second silsesquioxane copolymer 22. During the polymerization reaction, a composition ratio or weight ratio of the first silsesquioxane copolymer 26 and the second silsesquioxane copolymer 22 may be controlled, or a deposition thickness may be controlled to implement refraction characteristics and high-hardness characteristics required for a refraction layer of the present disclosure. The expression “high-hardness characteristics” refers to the characteristics of having excellent wear resistance and chemical resistance, thereby maintaining stable physical performance even under external impact, scratches, or chemical environments. Although the present disclosure is not limited thereto, high-hardness characteristics may refer to wear resistance of greater than or equal to 3 K and/or chemical resistance of greater than or equal to 1 K.

In one embodiment of the present disclosure, a composition ratio of the first silsesquioxane copolymer to the second silsesquioxane copolymer in the third silsesquioxane copolymer may be controlled to a weight ratio of 1:1 to 1:1.5 to be provided with refraction characteristics and high-hardness required for the present disclosure, but the present disclosure is not limited thereto. In case that a weight ratio of the first silsesquioxane copolymer to the second silsesquioxane copolymer in the third silsesquioxane is less than 1:0.5 or greater than 1:1.5, it may be difficult to form a refraction layer having low-reflection characteristics and high-hardness characteristics required in the present disclosure.

In one embodiment, the second silsesquioxane copolymer 22 provided in a lower portion of the refraction layer 20 of the present disclosure may have high-hardness characteristics.

Accordingly, similar to the window 1 of the present disclosure, a window 1 provided with a refraction layer 20 having a second silsesquioxane copolymer 22, a third silsesquioxane copolymer 24 and a first silsesquioxane copolymer 26 sequentially laminated (e.g., in the stated order) on a base film 10 may have low-reflection characteristics and hard coated characteristics due to a uniform refraction layer unlike a conventional window.

As described above, the refraction layer 20 having the second silsesquioxane copolymer 22, the third silsesquioxane copolymer 24 and the first silsesquioxane copolymer 26 sequentially laminated (e.g., in the stated order) on the base film 10 may have a lower portion, a middle portion, and an upper portion controlled to have different refraction indexes from one another to be provided with low-reflection characteristics.

In one embodiment, the first silsesquioxane copolymer 26 may be provided with a lowest refractive index among the first silsesquioxane copolymer 26 through the third silsesquioxane copolymer 24. In addition, a refractive index of the third silsesquioxane copolymer 24 may be smaller than a refractive index of the second silsesquioxane copolymer 22.

In one embodiment, the refractive index of the first silsesquioxane copolymer 26 may be greater than or equal to 1 and less than or equal to 1.7, the refractive index of the third silsesquioxane copolymer 24 may be greater than or equal to 1.2 and less than or equal to 1.8, and the refractive index of the second silsesquioxane copolymer 22 may be greater than or equal to 1.3 and smaller than or equal to 2, but the present disclosure is not limited thereto.

As described above, each deposition thickness of the first silsesquioxane copolymer 26 through the third silsesquioxane copolymer 24 in the refraction layer 20 may be controlled for the refraction layer 20 to be provided with low-reflection characteristics and high-hardness characteristics required for a window. Each deposition thickness of the first silsesquioxane copolymer 26 through the third silsesquioxane copolymer 22 may be controlled according to desired optical characteristics, i.e., desired refraction characteristics.

In one embodiment, a deposition thickness of the third silsesquioxane copolymer may be thinner than respective deposition thickness of the first silsesquioxane copolymer and the second silsesquioxane copolymer, and a deposition thickness of the first silsesquioxane copolymer may be thinner than a deposition thickness of the second silsesquioxane copolymer. In case that the deposition thickness of the third silsesquioxane copolymer is thicker than the deposition thickness of the first silsesquioxane copolymer, it may be difficult to implement low-reflection characteristics required for a window of the present disclosure, and flexibility of a window may be decreased.

In addition, if the deposition thickness of the third silsesquioxane copolymer is thicker than the deposition thickness of the first silsesquioxane copolymer, it may be difficult to satisfy hardness required for a window of the present disclosure and to manufacture a refraction layer provided with low-reflection characteristics and high-hardness characteristics.

In one embodiment, although the present disclosure is not limited thereto, the thickness of the first silsesquioxane copolymer may be greater than or equal to 50 nm and less than or equal to 100 nm, the thickness of the third silsesquioxane copolymer may be greater than or equal to 10 nm and less than or equal to 60 nm, and the thickness of the second silsesquioxane copolymer may be greater than or equal to 100 nm and less than or equal to 200 nm. In case that the thicknesses of the first silsesquioxane copolymer, the second silsesquioxane copolymer and the third silsesquioxane copolymer depart from the above ranges, it may be difficult to manufacture a window including a refraction layer provided with low-reflection characteristics and high-hardness characteristics.

In one embodiment, luminous reflectance (SCI) may be less than 0.8%, but the present disclosure is not limited thereto. The luminous reflectance indicates a degree of light reflection or transmission that allows human visual sense to perceive brightness of light. For the luminous reflectance, a spectrum colorimeter, for example, CM-2600d or CM-3600A manufactured by Konica Minolta may be used, but the present disclosure is not limited thereto. Upon using the spectrum colorimeter, total reflectance Y value (SCI) and diffuse reflectance Y value (SCE) corresponding to D light source and a 2 degree of viewing angle may be measured, and a value required for Y=SCI−SCE may be defined as a luminous reflectance. A window having luminous reflectance exceeding 0.8% may have excessively high reflectance and thus have difficulty in achieving reflection protection performance upon application requiring high contrast.

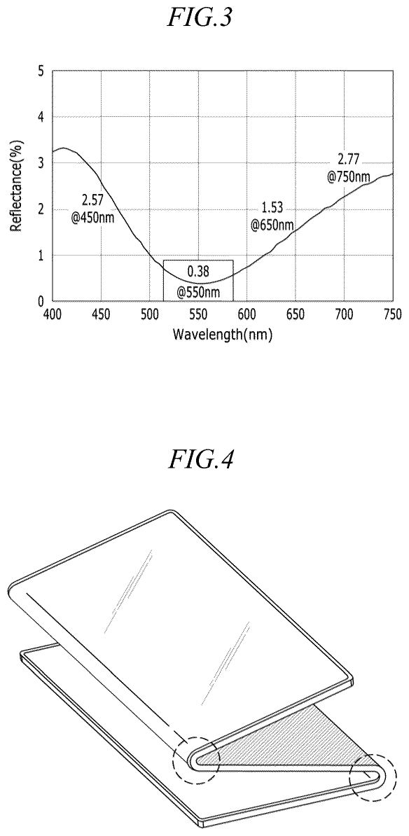

In relation with measurement of reflectivity, a vector diagram simulation result of a window manufactured according to one embodiment of the present disclosure is shown in FIG. 3. Referring to FIG. 3, reflectivity of a window of the present disclosure is shown to be as low as 0.38% at a depth of 550 nm.

FIG. 4 and FIG. 5 show a Z-fold structure (FIG. 4) and a G-fold structure (FIG. 5) of a conventional foldable electronic device. A crack does not occur in a foldable structure having a Z-fold structure or a G-fold structure and applied with a window of the present disclosure even under a folding condition with a radius of curvature of 1.4 R to 5 R, but the present disclosure is not limited thereto. This will be specified with reference to embodiments.

In one embodiment, the refraction layer may be a refraction layer of a single layer having low-reflection characteristics and high-hardness hard coated characteristics. In order to be provided with low-reflection characteristics, a conventional electronic device module, a window unit, or a protection layer PL unit has a high-refraction-index layer and a low-refraction-index layer repeatedly laminated to form multiple layers. Furthermore, in order to prevent reflection of light or penetration of light, an anti-fog (AF) coated layer is formed on the refraction layer.

However, a refraction layer of the present disclosure has a first silsesquioxane copolymer through a third silsesquioxane copolymer laminated in a certain order to have a structure in which a refractive index decreases towards an outermost region of the window on the base film. A window of the present disclosure may have the above structure to have low low-reflection characteristics, and a refraction layer of the present disclosure may have anti-fog (AF) characteristics to have a required effect of protection from reflection of light or penetration of light even without another AF coated layer. As the window has anti-fog (AF) characteristics, another AF coating may not be needed.

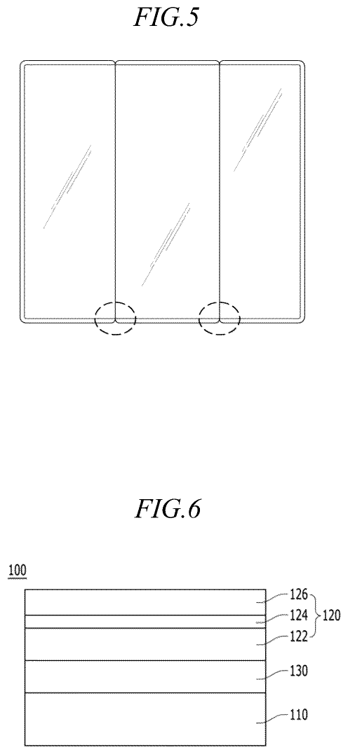

FIG. 6 is a cross-sectional view schematically illustrating a window having a coated layer on a base film according to one embodiment of the present disclosure. Referring to FIG. 6, a window 100 of the present disclosure may further include a coated layer 130 having high-hardness and high-flexibility characteristics on the base film 110. In addition, by including a refraction layer 120 (which includes a second silsesquioxane copolymer 122, a third silsesquioxane copolymer 124 and a first silsesquioxane copolymer 126) on the coated layer 130, not only high-hardness and high-flexibility characteristics of the refraction layer 120 may be imparted, but also wear resistance may be improved. The coated layer having high-hardness and high-flexibility characteristics may include an acrylate-based monomer, a siloxane resin, an epoxy resin, or an inorganic compound, but the present disclosure is not limited thereto. The inorganic material may SiO₂, TiO₂, Al₂O₃, ZrO₂, ZnO, AlN, Si₃N₄, or a combination thereof. The expression “high-flexibility characteristics” refers to the characteristics of a material to maintain a stable film thickness and functionality without cracking or delamination even under repeated folding or changes in curvature. Although the present disclosure is not limited thereto, the high-flexibility characteristics may be defined as absence of cracks or optical non-uniformities even after repeated folding tests with an inner curvature radius of less than or equal to 2.0 R and/or an outer curvature radius of greater than or equal to 4.0 R.

In order to manufacture a window 100 having much improved high-hardness and/or high-flexibility characteristics, elasticity and hardness of the coated layer 130 may be important.

In one embodiment, the elasticity modulus of the coated layer may be 6 GPa to 8 GPa at a thickness of the coated layer of 200 nm to 400 nm or 500 nm to 800 nm, but the present disclosure is not limited thereto. In case that the elasticity modulus of the coated layer is greater than or equal to 6 GPa, optical characteristics and mechanical characteristics of a film may be improved. However, in case that the elasticity modulus of the coated layer is less than 6 GPa, impact resistance of a protection layer PL may be decreased. In addition, in case that the elasticity modulus of the coated layer is greater than 8 GPa, shrinkage modification may be increased, and foldability of the electronic device including the protection layer PL may be partially deteriorated.

In one embodiment, hardness of the coated layer with a thickness of greater than or equal to 200 nm and less than or equal to 400 nm or greater than or equal to 500 nm and less than or equal to 800 nm may be greater than or equal to 0.6 GPa and less than or equal to 0.7 GPa, but the present disclosure is not limited thereto. In case that hardness of the coated layer with the above thickness is less than 0.6 GPa, impact resistance may be decreased, and in case that the hardness of the coated layer with the above thickness is greater than 0.7 GPa, foldability of the electronic device including the protection layer PL may be partially deteriorated.

A method of manufacturing a window according to one embodiment may include (I) first depositing for deposition of a second silsesquioxane copolymer represented by Formula 2 on a base film, (II) second depositing for deposition of a third silsesquioxane copolymer generated by a polymerization reaction through evaporation of a first silsesquioxane copolymer represented by Formula 1 and the second silsesquioxane copolymer on the deposited second silsesquioxane copolymer, and (III) third depositing for deposition of the first silsesquioxane copolymer on the deposited third silsesquioxane copolymer.

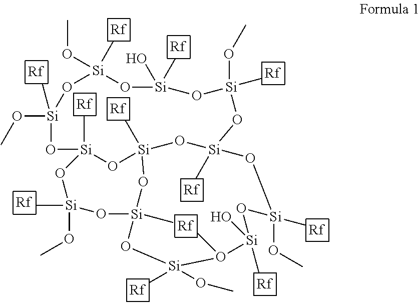

In Formula 1, Rf may be (CF₂)ₙ-M, M may be selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group (e.g., a phenyl group) with CF₃, a cyano group, a nitro group, a trifluoro methyl group, an amidino group, a hydrazine group, a hydrazono group, an alkoxy group, or any combination thereof, and n may be greater than or equal to 1 and less than or equal to 6.

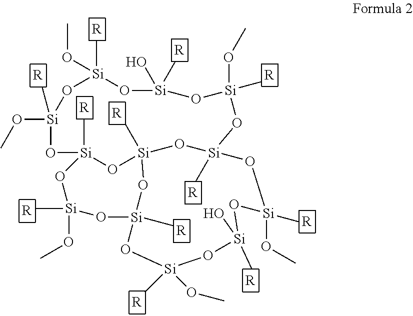

In Formula 2, R may be (—O—CO—Z)ₘ, Z may be selected from hydrogen, deuterium, a halogen, a hydroxyl group, a cyano group, a nitro group, a trifluoro methyl group, an amidino group, a hydrazine group, a hydrozono group, an alkoxy group, or any combination thereof, or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and m may be greater than or equal to 1 and less than or equal to 4.

In one embodiment, the first depositing (I) through the third depositing (III) may be carried out by a deposition polymerization method performed in a vacuum environment, but the present disclosure is not limited thereto.

In one embodiment, the first depositing (I) is a step of depositing a second silsesquioxane copolymer represented by Formula 2 on a base film. The second silsesquioxane copolymer may be evaporated by irradiating an electron beam or heating under a vacuum environment and deposited on the base film.

In one embodiment, the second depositing (II) is a step of depositing a third silsesquioxane copolymer generated by a polymerization reaction through evaporating a first silsesquioxane copolymer and the second silsesquioxane copolymer in a vacuum environment on the deposited second silsesquioxane copolymer.

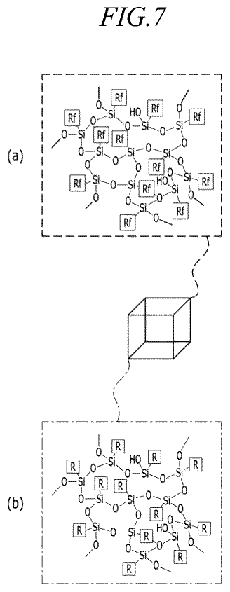

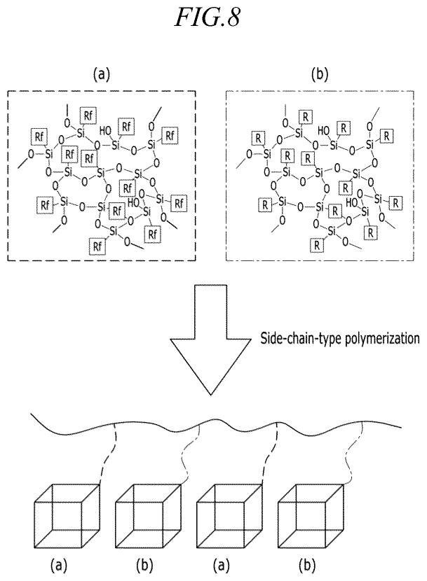

FIG. 7 and FIG. 8 are schematic diagram of a first silsesquioxane copolymer and a second silsesquioxane copolymer of a window manufactured according to one embodiment of the present disclosure polymerized to a polymer chain or polymer side chain. Referring to FIG. 7 and FIG. 8, a polymerization structure of the polymer chain (FIG. 7) or the polymer side chain (FIG. 8) represents a structure generated upon polymerization of the first silsesquioxane copolymer (a) and the second silsesquioxane copolymer (b) to polymerize a third silsesquioxane copolymer. Here, as chain polymerization has two functional groups, the third silsesquioxane copolymer may be provided with excellent bonding, and as side chain polymerization has 1 functional group, uniformity of the window may be improved. In the side chain polymerization, in case that bonding becomes weak and cross-linkage becomes weak due to 1 functional group, a cross-linking agent may be further included. Various known materials may be used as the cross-linking agent, and the cross-linking agent is not limited as long as it is able to form a window of the present disclosure. For example, the cross-linking agent may be zinc diacrylate or bisphenol A ethoxylate diacrylate, but the present disclosure is not limited thereto.

In one embodiment, the third depositing (III) may be a step of depositing the first silsesquioxane copolymer represented by Formula 1 on the deposited third silsesquioxane copolymer. The step may be carried out by a vacuum deposition polymerization method in which the first silsesquioxane copolymer is evaporated by irradiating an electron beam or heating under a vacuum environment and deposited on the base film for deposition on the third silsesquioxane copolymer.

In one embodiment, the deposition by the vacuum deposition polymerization method may form stable bonds of the copolymer, and thus has the advantages of high film thickness stability and excellent wear resistance. In addition, as no solvent is used for the vacuum deposition polymerization method, a problem with volatility of the solvent may be prevented, and as a single layer of the refraction layer may be formed without involving AF coating, the process may be simplified.

In one embodiment, the first depositing (I) may further include depositing a coated layer on the base film before the first depositing, but the present disclosure is not limited thereto.

The described method of manufacturing a window is described to involve formation of the refraction layer directly on the base film, but in another embodiment, the coated layer may be formed on the base film, and the refraction layer may be formed on the coated layer. The coated layer may be a coated layer having high-hardness and high-flexibility characteristics, but the present disclosure is not limited thereto. The coated layer may include an acrylate-based monomer, a siloxane resin, an epoxy resin or an inorganic compound, but the present disclosure is not limited thereto. The inorganic material may be SiO₂, TiO₂, Al₂O₃, ZrO₂, ZnO, AlN, Si₃N₄, or a combination thereof.

In one embodiment, the first depositing (I) through the third depositing (III) may involve vacuum deposition by irradiating an electron beam of greater than or equal to 200 KeV and less than or equal to 400 KeV in a vacuum environment. Through the vacuum deposition, the bonding of the copolymer in the above energy range may be more excellently formed, and the second silsesquioxane copolymer may be strongly attached to the base film to have excellent film quality. Furthermore, due to the above, mechanical properties, such as heat resistance, chemical resistance, and wear resistance, may be further improved, and it is difficult to form a crack. Accordingly, excellent foldability and high low-reflection characteristics may be achieved.

In one embodiment, the first silsesquioxane copolymer may be deposited to a thickness of greater than or equal to 50 nm and less than or equal to 100 nm, the second silsesquioxane copolymer may be deposited to a thickness of greater than or equal to 10 nm and less than or equal to 60 nm, and the third silsesquioxane copolymer may be deposited to a thickness of greater than or equal to 100 nm and less than or equal to 200 nm, but the present disclosure is not limited thereto.

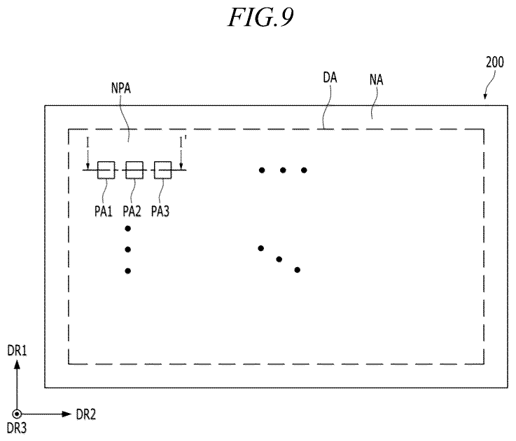

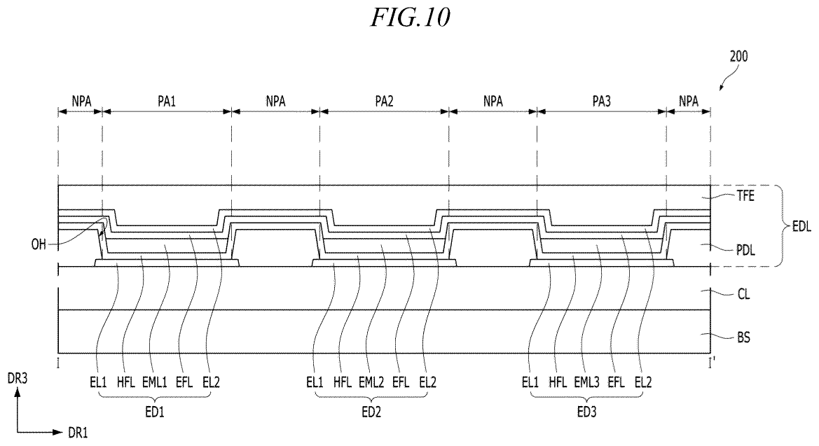

FIG. 9 is a plan view illustrating a display device according to one embodiment of the present disclosure, and FIG. 10 is a cross-sectional view taken along the I-I′ line shown in FIG. 9. Referring to FIG. 9 and FIG. 10, first to third directions DR1, DR2 and DR3 may be defined, in which a first direction DR1 and a second direction DR2 may intersect with each other in directions flush with a display device 200 illustrated in FIG. 9. A third direction DR3 may be in a direction of thickness of the display device, for example, normal to a plane defined by the first direction DR1 and the second direction DR2.

The display device 200 may be defined with a display area DA and a surrounding area NA defined outside of the display area. The display area DA may be an area configured to display an image and the surrounding area NA may be an area not configured to display an image. In certain embodiments, the surrounding area NA may not be provided.

Pixel areas PA1, PA2, and PA3 and a non-pixel area NPA may be defined in the display area DA. As light-emitting diodes ED1, ED2, and ED3 may be arranged to correspond to the pixel areas PA1, PA2, and PA3, respectively, the pixel areas may be areas configured to display emitted light.

The non-pixel area NPA may be an area defined among the pixel areas PA1, PA2, and PA3 and correspond to the pixel defining film PDL shown in FIG. 10.

Although it is illustrated in FIG. 9 that the pixel areas PA1, PA2, and PA3 have the same area, embodiments of the present disclosure are not limited to what are illustrated in FIG. 9, for example, in one or more embodiments, some of the pixel areas PA1, PA2, and PA3 may have different areas.

In one embodiment, a display device 200 may further include an optical layer on the display device layer EDL, but a display device according to one embodiment of the present disclosure is not limited thereto. The optical layer may be configured to reduce reflected light of external light. The optical layer may include a color filter layer, a color conversion layer, a touch-sensor layer, or a polarizing layer, but the present disclosure is not limited thereto.

In one embodiment, the display device 200 according to one or more embodiments of the present disclosure may further include a touch-sensor layer on the display device layer EDL. The touch-sensor layer may detect a coordination of a touch where a touch occurs. The touch-sensor layer may be interposed between the display device layer EDL and the optical layer.

In one embodiment, the display device 200 may include a substrate BS, a circuit layer CL, and a display device layer EDL, and the circuit layer CL and the display device layer EDL may be on the substrate BS.

The substrate BS may include, glass, ceramic, a metal, or a polymer resin such as a polyimide. Yet, embodiments of the present disclosure are not limited thereto, and the substrate BS may be an inorganic layer, an organic layer, or a composite material layer, and may be constituted with a single layer or a multilayer structure.

The circuit layer CL may be arranged on the substrate BS and include a plurality of wires and a plurality of transistors. In one or more embodiments, the circuit layer CL may include pixel transistors configured to drive light-emitting diodes ED1, ED2, and ED3 of the display device layer EDL. The circuit layer CL may include surrounding transistors arranged on a surrounding area NA and configured to output signals to control pixel transistors.

The display device layer EDL may include a pixel defining film PDL, light-emitting diodes ED1, ED2, and ED3, and an encapsulation layer TFE.

The pixel defining film PDL may include at least one insulating material selected from the group consisted of a polyimide, a polyamide, an acryl resin, a benzocyclobutene-based resin, and a phenol resin.

The light-emitting diodes ED1, ED2, and ED3 may each include a first electrode EL1, a hole functional layer HFL, a light-emission layer EML1, EML2, or EML3, an electron functional layer EFL, and a second electrode EL2.

The hole functional layer HFL may be configured to facilitate movement of a hole from the first electrode EL1 to a light-emission layer EML1, EML2, or EML3, and the electron functional layer EFL may be configured to facilitate movement of an electron from the second electrode EL2 to a light-emission layer EML1, EML2, or EML3. FIG. 10 exemplarily illustrates that the hole functional layer HFL is interposed between the first electrode EL1 and the light-emission layer EML1, EML2, or EML3 and the electron functional layer EFL is interposed between the second electrode EL2 and the light-emission layer EML1, EML2, or EML3. However, the present disclosure is not limited thereto, and the positions of the hole functional layer HFL and the electron functional layer EFL may be exchanged based on whether each of the first electrode EL1 and the second electrode EL2 is positively charged or negatively charged.

FIG. 10 illustrates one embodiment, in which light-emission layer EML1, EML2, and EML3 of the light-emitting diodes ED1, ED2, and ED3 is in an opening part OH defined in the pixel defining film PDL and the hole functional layer HFL, the electron functional layer EFL, and the second electrode EL2 are provided as a common layer in all light-emitting diodes ED1, ED2, and ED3. However, the present disclosure is not limited thereto, and unlike FIG. 10, at least one of the hole functional layer HFL and the electron functional layer HFL may be provided as patterned in the opening part OH defined in the pixel definition film PDL.

In one or more embodiments, at least some of the light-emitting diodes ED1, ED2, and ED3 may be configured to emit light in a different wavelength range. For example, in one or more embodiments, a first light-emitting diode ED1 may be configured to emit red light, a second light-emitting diode ED2 may be configured to emit green light, and a third light-emitting diode ED3 may be configured to emit blue light. However, embodiments of the present disclosure are not limited to this configuration. For example, a first light-emitting diode through a third light-emitting diode may be configured to emit light in substantially the same wavelength range, such as blue light.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include one or more selected from among acrylic compounds, epoxy compounds, and the like. In one or more embodiments, the encapsulation organic film may contain, but may not be limited to, one or more of photo-polymerizable organic materials. The encapsulation inorganic film may include, but may not be limited to, silicon nitride, silicon oxynitride, silicon oxide, titanium oxide, and/or aluminum oxide.

An electronic device according to one embodiment may include a display panel including a display device, and a window on an upper portion of the display panel, the window including a base film and a refraction layer on the base film. The refraction layer may include a first silsesquioxane copolymer including a fluoro-based silsesquioxane polymer chain, a second silsesquioxane copolymer including an acrylic-based silsesquioxane polymer chain, and a third silsesquioxane copolymer including the first silsesquioxane copolymer and the second silsesquioxane copolymer, and the refraction layer may have the second silsesquioxane copolymer, the third silsesquioxane copolymer and the first silsesquioxane copolymer sequentially laminated (e.g., in the stated order) on the base film.

An electronic device according to one embodiment may be applied to various electronic devices. The electronic device may include the described electronic device, and further include a module or a device having an additional function in addition to the electronic device.

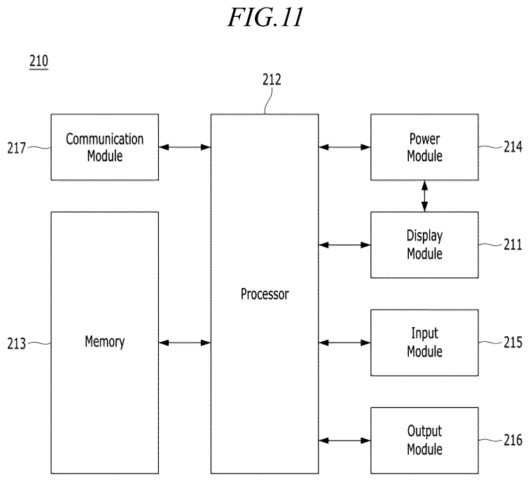

FIG. 11 is a block diagram of an electronic device according to one embodiment. Referring to FIG. 11, an electronic device 210 according to one embodiment may include a display module 211, a processor 212, a memory 213, and a power module 214. In one embodiment, the electronic device 210 may further include an input module 215, a non-image output module 216 and/or a communication module 217.

The electronic device 210 may be configured to output various information in a form of an image through the display module 211. In case that the processor 212 operates an application stored in the memory 213, the application may be configured to provide image information to a user through the display module 211. The power module 214 may include a power supply module, such as a power adaptor or a battery device, and a power conversion module configured to convert power supplied from the power supply module to generate power necessary for operation of the electronic device 210.

The input module 215 may provide input information to the processor 212 and/or the power module 211. The non-image output module 216 may be configured to receive acoustic, haptic or light-emission information in addition to image information provided from the processor to provide the information to a user. The communication module 217 is a module configured to transmit and receive information between the electronic device 210 and an external device and include a receiver and a transmitter.

At least one of the above-described components of the electronic device 210 may be included within the electronic device according to the above-described embodiments. Additionally, certain individual modules included functionally within a single module may be provided within the display device while other individual modules may be provided outside the electronic device. For instance, the display device may include the display module 211, and the processor 212, memory 213, and power module 214 may be provided as other devices within the electronic device 210 but not within the display device.

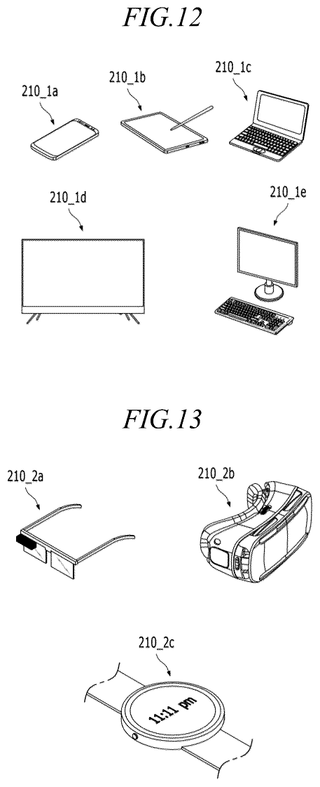

FIG. 12 through FIG. 14 are schematic diagrams of electronic devices according to various embodiments. FIG. 12 through FIG. 14 illustrate examples of various electronic devices including electronic devices according to embodiments.

As examples of an electronic device, FIG. 12 illustrates a smartphone 210_1a, a tablet PC 210_1b, a laptop 210_1c, a TV 210_1d, and a desktop monitor 210_1e.

A smartphone 210_1a may include an input module, such as a touch sensor, and a communication module in addition to a display module 211. A smartphone 210_1a may be configured to process information received from the communication module or other input modules to display information through the display module of the electronic device.

Similar to the smartphone 210_1a, a tablet PC 210_1b, a laptop 210_1c, a TV 210_1d, and a desktop monitor 210_1e may also include a display module and an input module, and in some embodiments, a communication module may be further included.

FIG. 13 illustrates an example in which an electronic device including a display module is applied to a wearable electronic device. Examples of a wearable electronic device may be smart glasses 210_2a, a head-mounted display 210_2b, or a smart watch 210_2c.

Smart glasses 210_2a and a head-mounted display 210_2b may include a display module configured to emit a display image and a reflector configured to reflect a display screen towards eyes of a user. Accordingly, an image of virtual reality or augmented reality may be provided to a user.

A smart watch 210_2c may include a biometric sensor as an input device and be configured to provide biometric information recognized through the biometric sensor to a user through a display module.

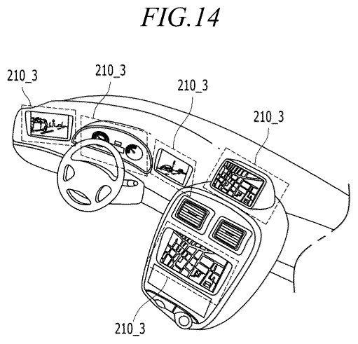

FIG. 14 illustrates an example in which an electronic device including a display module is applied to a vehicle. For example, an electronic device 2103 may be applied to, for example, a vehicle instrument panel, center fascia, center information display (CID) on a dashboard of a vehicle, or a room mirror display replacing a side mirror.

In one or more embodiments, an electronic device applicable with an electronic device according to one or more embodiments may include not only devices mainly for displaying an image, such as a billboard, an electronic board, and a game console, but also various home appliances displaying information through a display module, such as a refrigerator, a washing machine, a dryer, an air conditioner, or a robot vacuum cleaner. In addition, in case that a display module allows penetration of light, an electronic device according to one or more embodiments may be applicable to an electronic device, such as a smart window, or a transparent electronic device displaying an image along with a background. For example, an electronic device according to one or more embodiments may be applicable to one of various electronic devices, such as a plane panel display, a curved display, a television, a billboard, a computer monitor, a medical monitor, a head mounted display (HMD), a light for indoor light, an outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle electronic device, an outdoor electronic device, a theater screen, a stadium screen, a signboard, a game console, and home appliances displaying information through a display module, such as a refrigerator, a washing machine, a dryer, an air conditioner, and a robot vacuum cleaner. However, types of an electronic device according to one embodiment are not limited to the above examples, and an electronic device according to one or more embodiments of the present disclosure may be applicable to various undescribed electronic devices.

Hereinafter, the present disclosure will be described with reference to embodiments in detail.

### Embodiment

### Embodiment 1. Manufacture of a Window Including a Refraction Layer of the Present Disclosure

A polyethylene terephthalate (PET) film was used as a base film and manufactured in a dry process. A second silsesquioxane copolymer was introduced into a deposition device, and electron beam energy was applied for vacuum deposition on a base film. Subsequently, a third silsesquioxane copolymer generated through a polymerization reaction by having a first silsesquioxane copolymer and the second silsesquioxane copolymer applied with an electron beam for evaporation and evaporated was vacuum deposited on the deposited second silsesquioxane copolymer. The first silsesquioxane copolymer was applied with an electron beam for vacuum deposition on the deposited third silsesquioxane copolymer. Energy of the electron energy beam applied to the copolymer was greater than or equal to 200 KeV and less than or equal to 400 KeV.

A fluoro-based silsesquioxane copolymer chain of a compound represented by Formula 1, in which M of Rf was CF₃ and n was 4, was used as the first silsesquioxane copolymer forming the refraction layer. An acrylic-based silsesquioxane copolymer chain of Formula 2, in which Z was CH₂CH₂CH₂CH₃ and x was 1, was used as the second silsesquioxane copolymer. A refractive index of the first silsesquioxane copolymer was 1.36, a refractive index of the second silsesquioxane copolymer was 1.51, and a refractive index of the third silsesquioxane copolymer was 1.43. Deposition thicknesses of the second silsesquioxane copolymer, the third silsesquioxane copolymer and the first sislesquioxane copolymer in the refraction layer were, respectively, 86 nm, 26 nm, and 173 nm.

### Comparative Example 1

A polyimide (PI) film, which was a film included in a commercially available electronic device module, was used as a base film. A hard coated layer was provided, and a refraction layer of 5 layers was formed by repeated lamination of SiOₓ/Nb₂O₃ through a dry process. An AF coated layer was provided on the refraction layer thorough a wet process.

### Comparative Example 2

A polyethylene terephthalate (PET) film, which was a commercially available single-product window or PL layer, was used as a base film. A hard-coated layer was provided on the film, and a refraction layer of 5 layers was formed by repeated lamination of SiOₓ/Nb₂O₃ through a dry process. An AF coated layer was provided on the refraction layer through a dry process.

### Comparative Example 3

A polyethylene terephthalate (PET) film was used as a base film. A hard-coated layer was deposited on the film, and hollow/nano silica was used in a wet process for lamination of three layers. An AF coated layer was provided on the refraction layer through a wet process.

### Results

Experimental Example 1. Non-Crack Characteristics of a Window Having Low Curvature

Generation of a crack at various curvatures was examined for Embodiment 1, Comparative Example 1, and Comparative Example 2 of the present disclosure. For reliability verification, evaluation of temperature humidity bias (THB) under an electric bias, evaluation of a possibility of a defective product due to hot carrier effects (a low temperature operating life test; LTOL), and reliability evaluation under a high temperature and humid condition (unbiased highly accelerated stress test; UHAST) were conducted.

Upon a module reliability evaluation, a crack or a bubble was shown in a low-reflection structure of Comparative Example 1 and Comparative Example 2 at a level of 1.5 R to 2.3 R. However, no crack or bubble was shown in Embodiment 1 under a condition of 1.5 R (In), and therefore, flexibility and durability were shown to be provided. This plays a very important role in improving reliability and lifespan of a product.

According to the above result, a window including a refraction layer according to the present disclosure may prevent generation of a crack, which may be generated in a low-curvature structure upon folding operation.

### Experimental Example 2. Comparison of Window Characteristics

In order to compare window characteristics of Comparative Example 1 through Comparative Example 3 and Embodiment 1 of the present disclosure, film thickness uniformity, luminous reflectance, reflected color, wear resistance and chemical resistance according to a method of folding and a radius of curvature were evaluated and shown in Table 1.

TABLE 1

| | | Module | | Single Product (window or PL) | |
|---|---|---|---|---|---|
| Characteristics | | Comparative | Comparative | Comparative | |
| Comparison | | Example 1 | Example 2 | Example 3 | Embodiment 1 |
| Folding method/radius | | Out/5.6R | In/1.4R | In/2.0R | In/1.5R |
| of curvature | | | | | Out/4R |
| Film thickness uniformity | | Stable | — | Stable | Stable |
| Luminous reflectance (%) | | 2.1 | 6.5 | 0.25 | Less than 1.0 |
| | | | | | (PL 8.39) |
| Reflected Color | a* | 2.29 | −0.5 | 3.5 | 0.66 |
| | b* | −12.5 | −3.58 | −9.0 | −2.36 |

| | | | | |
|---|---|---|---|---|
| Wear resistance/chemical | 2.5K/1K | 4.5K/1.5K | 4K/1.5K | 5K/2K |
| resistance | | | | |

| | |
|---|---|
| Manufacture method | R2R (Roll-to-Roll) |

Referring to Table 1, low-reflectance characteristics may be shown by reflected brightness C(=√(a²+b²)). The closer the values of both a and b are to zero, the closer the reflected light is to achromatic, and the more improved low-reflectance characteristics are shown. In addition, the lower the values of a and b are, the higher visibility is as less reflectance occurs and an amount of transmitted light decreases. Particularly, it is known that when the luminous reflectance is less than or equal to 2.0%, sufficient anti-reflection characteristics are shown. Furthermore, when the value of the C is less than 6.0, sufficient resistance to a fingerprint can be obtained. The expression “low-reflectance characteristics” (or “low-reflection characteristics”) refers to the characteristics of minimizing reflection of external light on the surface of a material, thereby improving visibility and transmittance and suppressing glare and/or interference caused by reflection. Although the present disclosure is not limited thereto, the low reflection characteristics may be defined as having a luminous reflectance of less than or equal to 2.0%.

In light of the above, Embodiment 1 is shown to have superior visibility, low-reflection characteristics, and resistance to a fingerprint than Comparative Example 1 through Comparative Example 3.

Furthermore, in Embodiment 1, no crack was formed even under a condition of a radius of curvature of 1.5 R (panel bent sufficient to wrap around a cylinder having a radius of 1.5 mm) and 4 R (panel bent sufficient to cover an inner surface of a cylinder having a radius of 4 mm).

Wear resistance, chemical resistance and foldability are in a trade-off relationship. In a case of a conventional window, when wear resistance or chemical resistance increases, foldability decreases. However, Embodiment 1 having high wear resistance (5K) and chemical resistance (2K) showed superior foldability than Comparative Example 1 through Comparative Example 3.

In conclusion, Embodiment 1 provided with a refraction layer according to the present disclosure showed not only superior low-reflectance characteristics (low-refraction characteristics) but also superior foldability (high-hardness characteristics) than Comparative Example 1 through Comparative Example 3.

While certain embodiments of the present disclosure have been described above, the descriptions are merely for particular description of the present disclosure, and the present disclosure is not limited thereto. Anyone ordinarily skilled in the art to which the present disclosure pertains shall appreciate that there may be a variety of modifications and permutations of the present disclosure without departing from the technical ideas and scope of the present disclosure that are defined in the appended claims. Simple modifications and permutations of the present disclosure all belong to the scope of the present disclosure. Therefore, the technical scope of the present disclosure should be interpreted by the scope of the claims and equivalents thereof, instead of being restricted to the disclosed description in the Detailed Description.

What is claimed is:

1. A window comprising:
a base film; and
a refraction layer on the base film,
wherein the refraction layer comprises a first silsesquioxane copolymer comprising a fluoro-based silsesquioxane polymer chain; a second silsesquioxane copolymer comprising an acrylic-based silsesquioxane polymer chain; and a third silsesquioxane copolymer comprising the first silsesquioxane copolymer and the second silsesquioxane copolymer, and
wherein the refraction layer has the second silsesquioxane copolymer, the third silsesquioxane copolymer and the first silsesquioxane copolymer sequentially laminated on the base film.

2. The window of claim 1,
wherein the first silsesquioxane copolymer is a compound represented by Formula 1,
wherein the second silsesquioxane copolymer is a compound represented by Formula 2, 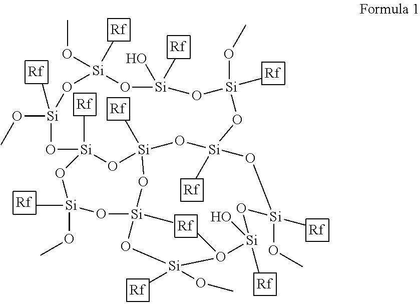
wherein in Formula 1:
Rf is (CF₂)ₙ-M;
M is selected from CF₃, a cyano group, a nitro group, a trifluoro methyl group, an amidino group, a hydrazino group, a hydrazono group, an alkoxy group, or any combination thereof, or a substituted or unsubstituted alkyl group, alkenyl group, and aryl group with CF₃, a cyano group, a nitro group, a trifluoro methyl group, an amidino group, a hydrazino group, a hydrazono group, an alkoxy group, or any combination thereof, and
n is greater than or equal to 1 and less than or equal to 6, and 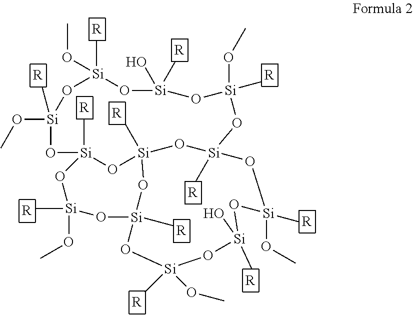
wherein in Formula 2:
R is (—O—CO—Z)ₘ;
Z is selected from hydrogen, deuterium, a halogen, a hydroxyl group, a cyano group, a nitro group, a trifluoro methyl group, an amidino group, a hydrazine group, a hydrozono group, an alkoxy group, or any combination thereof, or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and
m is greater than or equal to 1 and less than or equal to 4.

3. The window of claim 1,
wherein in the third silsesquioxane copolymer, a weight ratio of the first silsesquioxane copolymer to the second silsesquioxane copolymer is 1:1 to 1:1.5.

4. The window of claim 1,
wherein a refractive index of the first silsesquioxane copolymer and a refractive index of the third silsesquioxane copolymer are less than a refractive index of the second silsesquioxane copolymer, and
wherein the refractive index of the first silsesquioxane copolymer is less than the refractive index of the third silsesquioxane copolymer.

5. The window of claim 1,
wherein the refractive index of the first silsesquioxane copolymer is 1 to 1.7,
wherein the refractive index of the third silsesquioxane copolymer is 1.2 to 1.8, and
wherein the refractive index of the second silsesquioxane copolymer is 1.3 to 2.

6. The window of claim 1,
wherein a deposition thickness of the third silsesquioxane copolymer is less than a respective deposition thickness of the first silsesquioxane copolymer and the second silsesquioxane copolymer, and
wherein a deposition thickness of the first silsesquioxane copolymer is less than a deposition thickness of the second silsesquioxane copolymer.

7. The window of claim 1,
wherein the deposition thickness of the first silsesquioxane copolymer is greater than or equal to 50 nm and less than or equal to 100 nm,
wherein the deposition thickness of the third silsesquioxane copolymer is greater than or equal to 10 nm and less than or equal to 60 nm, and
wherein the deposition thickness of the second silsesquioxane copolymer is greater than or equal to 100 nm and less than or equal to 200 nm.

8. The window of claim 1,
wherein a luminous reflectance of the window is less than or equal to 0.8%, and
wherein a crack does not occur in the window under a folding condition of a radius curvature greater than or equal to 1.4 R and less than or equal to 5 R.

9. The window of claim 1,
wherein the refraction layer is a single layer refraction layer having low-reflection characteristics and high-hardness hard-coated characteristics.

10. The window of claim 1,
wherein the refraction layer has anti-fog characteristics.

11. The window of claim 1, further comprising a coated layer having high-hardness and high-flexibility characteristics on the base film.

12. The window of claim 11,
wherein an elasticity of the coated layer is greater than or equal to 6 GPa and less than or equal to 8 GPa at a depth greater than or equal to 200 nm and less than or equal to 400 nm or greater than or equal to 500 nm and less than or equal to 800 nm.

13. The window of claim 11,
wherein a hardness of the coated layer is greater than or equal to 0.6 GPa and less than or equal to 0.7 GPa at a depth greater than or equal to 200 nm and less than or equal to 400 nm or greater than or equal to 500 nm and less than or equal to 800 nm.

14. A method of manufacturing a window comprising:
(I) first depositing for deposition of a second silsesquioxane copolymer represented by Formula 2 on a base film;
(II) second depositing for deposition of a third silsesquioxane copolymer generated through a polymerization reaction by evaporating a first silsesquioxane copolymer represented by Formula 1 and the second silsesquioxane copolymer on the deposited second silsesquioxane copolymer, and
(III) third depositing for deposition of the first silsesquioxane copolymer on the deposited third silsesquioxane copolymer,
for sequential deposition, 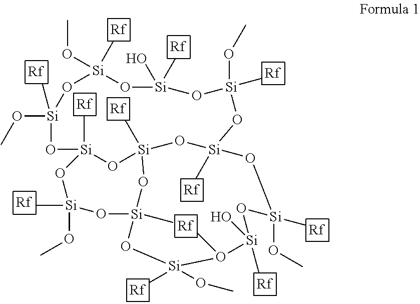
wherein in Formula 1:
Rf is (CF₂)ₙ-M;
M is selected from CF₃, a cyano group, a nitro group, a trifluoro methyl group, an amidino group, a hydrazine group, a hydrazono group, an alkoxy group, or any combination thereof, or a substituted or unsubstituted alkyl group, alkenyl group, and aryl group with CF₃, a cyano group, a nitro group, a trifluoro methyl group, an amidino group, a hydrazine group, a hydrazono group, an alkoxy group, or any combination thereof, and
n is greater than or equal to 1 and less than or equal to 6, and 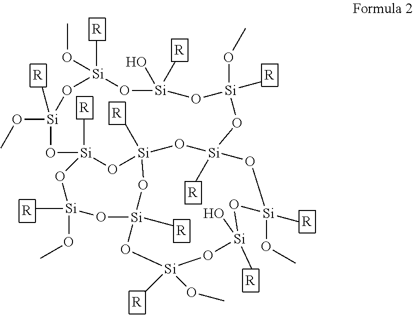
wherein in Formula 2:
R is (—O—CO—Z)ₘ,
Z is selected from hydrogen, deuterium, a halogen, a hydroxyl group, a cyano group, a nitro group, a trifluoro methyl group, an amidino group, a hydrazine group, a hydrozono group, an alkoxy group, or any combination thereof; or a substituted or unsubstituted alkyl group having 1 to 10 carbons, alkenyl group having 2 to 10 carbons, alkynyl group having 2 to 10 carbons, and aryl group having 6 to 30 ring-forming carbons with hydrogen, deuterium, a halogen, a hydroxyl group, a cyano group, a nitro group, a trifluoro methyl group, an amidino group, a hydrazine group, a hydrazono group, an alkoxy group, or any combination thereof, and
m is greater than or equal to 1 and less than or equal to 4.

15. The method of manufacturing a window of claim 14,
wherein in the polymerization reaction, the first silsesquioxane copolymer and the second silsesquioxane copolymer are polymerized to a polymer chain or a polymer side chain.

16. The method of manufacturing a window of claim 14,
further comprising depositing a coated layer on the base film prior to the first depositing (I).

17. The method of manufacturing a window of claim 14,
wherein the first depositing (I) through the third depositing (III) are performed through vacuum deposition by irradiating an electron beam of greater than or equal to 200 KeV and less than or equal to 400 KeV in a vacuum environment.

18. The method of manufacturing a window of claim 14,
wherein the first silsesquioxane copolymer is deposited to a thickness of greater than or equal to 50 nm and less than or equal to 100 nm,
wherein the second silsesquioxane copolymer is deposited to a thickness of greater than ore qual to 10 nm and less than or equal to 60 nm, and
wherein the third silsesquioxane copolymer is deposited to a thickness of greater than or equal to 100 nm and less than or equal to 200 nm.

19. An electronic device comprising a display panel comprising a display device, and a window on an upper portion of the display panel,
wherein the window comprises a base film and a refraction layer on the base film,
wherein the refraction layer comprises:
a first silsesquioxane copolymer comprising a fluoro-based silsesquioxane polymer chain;
a second silsesquioxane copolymer comprising an acrylic-based silsesquioxane polymer polymer; and
a third silsesquioxane copolymer comprising the first silsesquioxane copolymer and the second silsesquioxane copolymer, and
wherein the refraction layer has the second silsesquioxane copolymer, the third silsesquioxane copolymer and the first silsesquioxane copolymer sequentially laminated on the base film.

20. The electronic device of claim 19,
wherein the electronic device is a flat panel display, a curved display, a television, a billboard, a computer monitor, a medical monitor, a head mounted display (HIMD), an indoor or outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual or augmented reality display, a video wall comprising multiple displays tiled together, a vehicle electronic device, an outdoor electronic device, a theater screen, a stadium screen, a scoreboard, a signboard, a game console, a refrigerator, a washing machine, a dryer, an air conditioner, or a robot vacuum cleaner.
